(19) United States
(12) Patent Application Publication
(10) Pub. No.: US 2026/0214816 A1
(43) Pub. Date: Jul. 23, 2026

(54) Anti-Tamper Securing Mechanism and Operation Method thereof

(71) Applicant: Nanning FuLian FuGui Precision Industrial Co., Ltd., Nanning (CN)

(72) Inventor: DONG QIN, Shenzhen (CN)

(21) Appl. No.: 19/045,890

(22) Filed: Feb. 5, 2025

(30) Foreign Application Priority Data
Jan. 22, 2025 (CN) 202510104509.9

(51) Int. Cl. H05K 5/02

(52) U.S. Cl. CPC H05K 5/0208; H05K 5/0221

(57) ABSTRACT

An anti-tamper securing mechanism and an operation method thereof are provided. The anti-tamper securing mechanism includes a screw bolt, a rotation cover, a connection element, and a main elastic element. The screw bolt includes a fastening body; a partition element affixed within the fastening body; and a temporary element, affixed to the partition element. The rotation cover is rotatably disposed in the fastening body. The connection element is movably and rotatably disposed in the fastening body, and connected to the rotation cover. The main elastic element is between the connection element and the partition element. When the fastening body is fastened on an object, the temporary element is broken off from the partition element by further rotating the rotation cover relative to the fastening body.

### FIELD

The subject matter herein generally relates to anti-tamper securing mechanisms.

### BACKGROUND

The assembly of electronic devices generally involves installing a variety of electronic components in a chassis and then securing the chassis with screws. However, a regular screwdriver can be used to easily remove screws to open the chassis, and then remove the electronic components inside the chassis, causing damage to the electronic device.

In addition, if the chassis is only secured with screws, it is possible that the storage device inside the chassis can be easily stolen, resulting in significant losses of important data.

### BRIEF DESCRIPTION OF THE DRAWINGS

Many aspects of the present disclosure are better understood with reference to the following drawings. The components in the drawings are not necessarily drawn to scale, the emphasis instead being placed upon clearly illustrating the principles of the present disclosure. It will be appreciated that for simplicity and clarity of illustration, where appropriate, reference numerals have been repeated among the different figures to indicate corresponding or analogous elements.

FIG. 1 is a cross-sectional view of an anti-tamper securing mechanism in accordance with an embodiment of the present disclosure.

FIG. 2 is a perspective view of the anti-tamper securing mechanism shown in FIG. 1.

FIG. 3 is a cross-sectional, exploded view of the anti-tamper securing mechanism shown in FIG. 2.

FIG. 4 is another exploded view of the anti-tamper securing mechanism shown in FIG. 2.

FIG. 5 and FIG. 6 are cross-sectional views of the anti-tamper securing mechanism in FIG. 1, the anti-tamper securing mechanism is in operation processes in accordance with an embodiment of the present disclosure.

### DETAILED DESCRIPTION

It will be appreciated that for simplicity and clarity of illustration, where appropriate, reference numerals have been repeated among the different figures to indicate corresponding or analogous elements. In addition, numerous specific details are set forth in order to provide a thorough understanding of the embodiments described herein. However, it will be understood by those of ordinary skill in the art that the embodiments described herein can be practiced without these specific details. In other instances, methods, procedures, and components have not been described in detail so as not to obscure the related relevant feature being described. Also, the description is not to be considered as limiting the scope of the embodiments described herein. The drawings are not necessarily to scale and the proportions of certain parts have been exaggerated to better illustrate details and features of the present disclosure.

The disclosure is illustrated by way of embodiments and not by way of limitation in the figures of the accompanying drawings, in which like references indicate similar elements. It should be noted that references to “an” or “one” embodiment in this disclosure are not necessarily to the same embodiment, and such references mean “at least one.”

The term “connect” is defined as directly or indirectly through intervening components, and is not necessarily limited to physical connections. The connection can be such that the objects are permanently connected or releasably connected. The term “comprising,” when utilized, means “including, but not necessarily limited to”; it specifically indicates open-ended inclusion or membership in the so-described combination, group, series, and the like.

In the present disclosure, an anti-tamper securing mechanism allows the user to use a regular securing tool, such as a screwdriver, to secure a chassis. However, a specific disassembly tool is required to open the chassis, which increases the difficulty of opening the chassis.

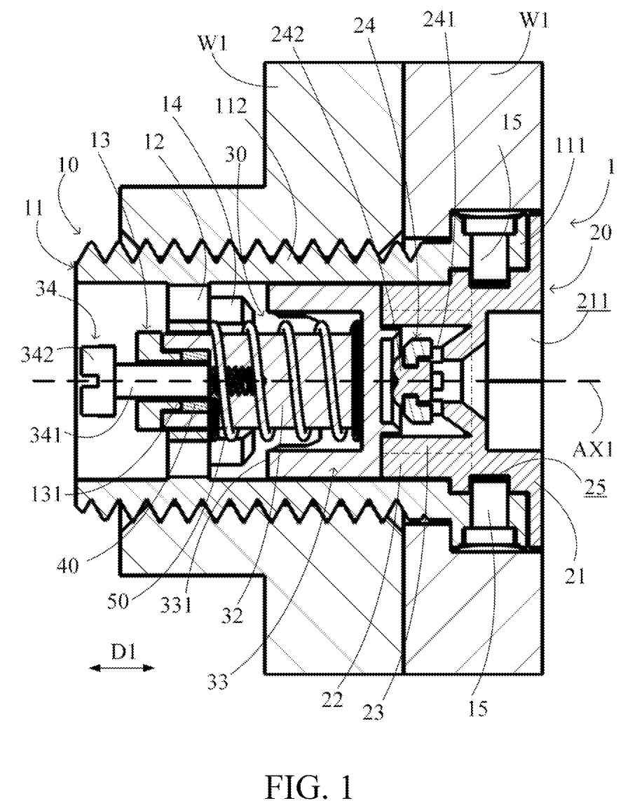

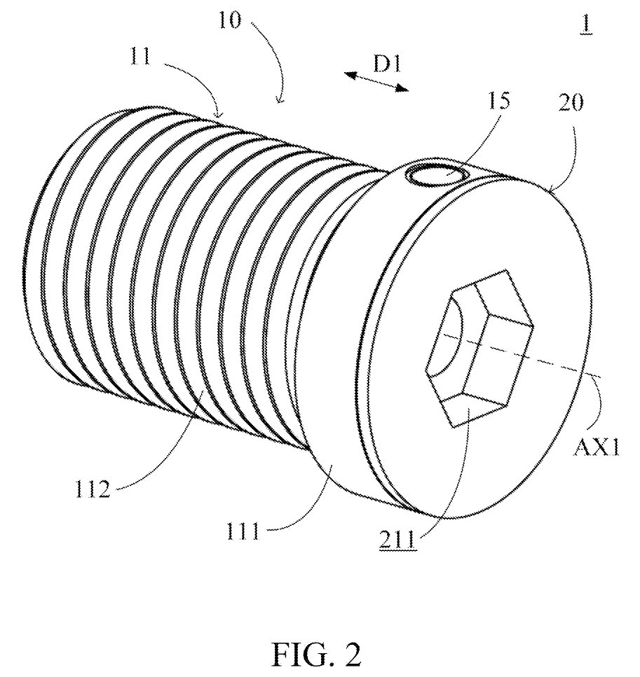

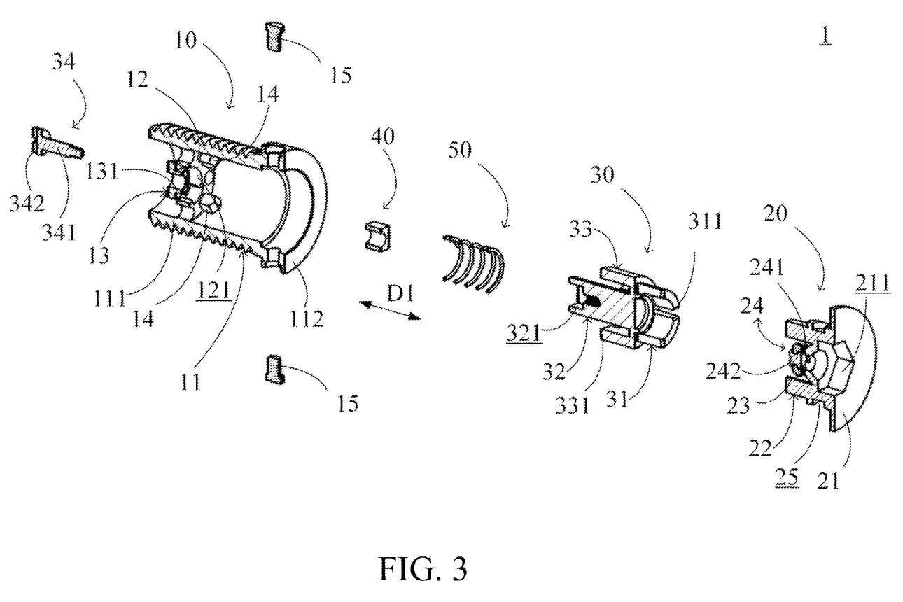

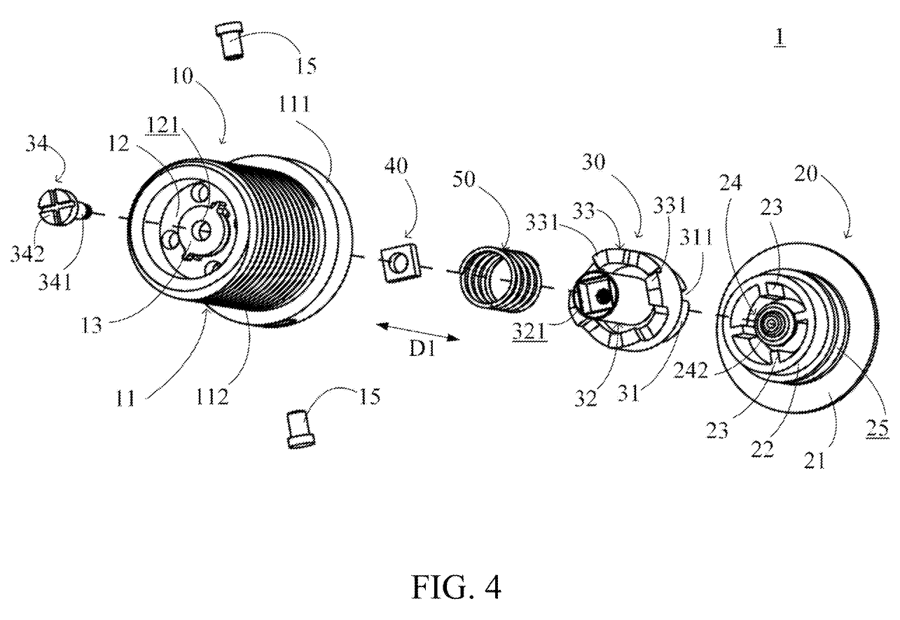

FIG. 1 is a cross-sectional view of an anti-tamper securing mechanism 1 in accordance with an embodiment of the present disclosure. FIG. 2 is a perspective view of the anti-tamper securing mechanism 1 shown in FIG. 1. FIG. 3 is a cross-sectional exploded view of the anti-tamper securing mechanism 1 shown in FIG. 2. FIG. 4 is another exploded view of the anti-tamper securing mechanism 1 shown in FIG. 2. The anti-tamper securing mechanism 1 can be fastened to two objects W1, thereby combining the object W1. For example, one object W1 can be a chassis, and the other object W1 can be a cover of the chassis. The anti-tamper securing mechanism 1 includes a screw bolt 10, a rotation cover 20, a connection element 30, an inner elastic element 40, and a main elastic element 50.

The screw bolt 10 can be fastened to the objects W1, and includes a fastening body 11, a partition element 12, a temporary element 13, and engaging protrusions 14. The fastening body 11, the partition element 12, the temporary element 13, and the engaging protrusions 14 can be integrally formed, and can be made of the same materials, such as metal. The fastening body 11 may be an elongated structure, and extends in a longitudinal direction D1. The fastening body 11 may be a hollow structure, and may be a cylindrical structure. Moreover, an imaginary central axis AX1 may be parallel to the longitudinal direction D1, and extend through the center of the fastening body 11.

The fastening body 11 includes a head portion 111, and a screw rod 112. The head portion 111 and the screw rod 112 may be hollow structures, and may be cylindrical structures. The head portion 111 is connected to the screw rod 112, and the screw rod 112 has screw thread formed on the outer surface. In the embodiment, the diameter of the head portion 111 is longer than the diameter of the screw rod 112. The diameter of the head portion 111 and the diameter of the screw rod 112 are measured in the same direction, which is perpendicular to the imaginary central axis AX1. The head portion 111 and the screw rod 112 can be integrally formed, and can be made of the same materials, such as metal.

The partition element 12 is affixed within the screw rod 112 of the fastening body 11, and extends perpendicular to the imaginary central axis AX1. The temporary element 13 is attachable to the partition element. The engaging protrusions 14 is affixed within the screw rod 112. In the embodiment, the temporary element 13 and the engaging protrusions 14 are connected to opposite sides of the partition element 12. In other words, the partition element 12 is between the temporary element 13 and the engaging protrusion 14. The engaging protrusion 14 is closer to the head portion 111 than the temporary element 13. The imaginary central axis AX1 extends through the center of the partition element 12 and the center of the temporary element 13, and the engaging protrusions 14 are arranged around the imaginary central axis AX1.

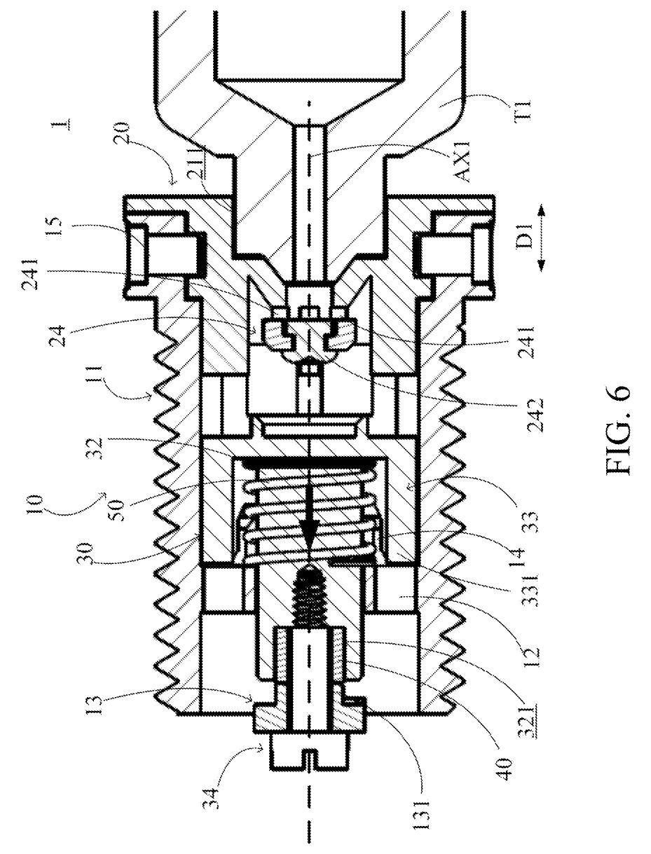

The rotation cover 20 is rotatably disposed in the head portion 111 of the fastening body 11. The rotation cover 20 includes a cover portion 21, a connection post 22, a restriction ribs 23, and a ventilation post 24. The cover portion 21, the connection post 22, the restriction ribs 23, and the ventilation post 24 be integrally formed, and can be made of the same materials, such as metal or plastic. The imaginary central axis AX1 extends through the centers of the cover portion 21, the connection post 22, and the ventilation post 24, and the restriction ribs 23 are arranged around the imaginary central axis AX1. The cover portion 21 is in the head portion 111 of the fastening body 11, and exposed from the screw bolt 10. The cover portion 21 has a tool groove 211. A securing tool (not shown in drawings) and a disassembly tool T1 (as shown in FIG. 6) can be inserted in the tool groove 211 to rotate the rotation cover 20. In the embodiment, the securing tool may be a screwdriver.

The connection post 22 is connected to the cover portion 21, and in the head portion 111 and/or the screw rod 112. The connection post 22 may be a hollow structure. The restriction rib 23 is affixed to the connection post 22, and in the connection post 22. Moreover, the restriction rib 23 extends toward the imaginary central axis AX1, and parallel to the imaginary central axis AX1. The ventilation post 24 is affixed to the cover portion 21, and is in the connection post 22 and the fastening body 11. The ventilation post 24 includes one or more ventilation opening 241. The ventilation opening 241 is communicated with the tool groove 211.

In the embodiment, the ventilation opening 241 is formed on the outer wall of the ventilation post 24, and separated from the imaginary central axis AX1. The end of the ventilation post 24 has an obstruction wall 242. The imaginary central axis AX1 extends through the center of the tool groove 211 and the center of the obstruction wall 242. Therefore, small object, such as dust, falling between the rotation cover 20 and the connection element 30 through the ventilation opening 241 can be reduced.

The rotation cover 20 further includes a position groove 25, formed on the outer wall of the cover portion 21 and/or the outer wall of connection post 22. The screw bolt 10 further includes limiting elements 15, extending into the position groove 25. In the embodiment, the limiting element 15 may be a pin extending into the position groove 25 via the head portion 111 of the fastening body 11. The position groove 25 may be an annular structure around the imaginary central axis AX1. The limiting element 15 and the position groove 25 restricts the rotation cover 20 to be rotated relative to the fastening body 11 about the imaginary central axis AX1. In other words, the limiting element 15 and the position groove 25 prohibit the rotation cover 20 from moving along the imaginary central axis AX1 relative to the fastening body 11.

The connection element 30 is movably and rotatably disposed in the fastening body 11, and connected to the rotation cover 20. The connection element 30 can move relative to the rotation cover 20 in the longitudinal direction D1. The connection element 30 includes a guiding structure 31, a shaft 32, and a driving structure 33, and a holding structure 34. The guiding structure 31, the shaft 32, and the driving structure 33 are integrally formed, and can be made of the same materials, such as metal or plastic. The guiding structure 31 extends in the longitudinal direction D1, and may be a hollow structure. The guiding structure 31 includes restriction slots 311. The restriction slots 311 extends in the longitudinal direction D1, and are separated from each other. In other words, the restriction slots 311 are arranged around the imaginary central axis AX1. The restriction rib 23 of the rotation cover 20 is in the restriction slot 311. The restriction slots 311 and the restriction rib 23 can restricts the movement of the connection element 30 in the longitudinal direction D1 relative to the fastening body 11 and the rotation cover 20, and can prohibit the connection element 30 from rotating relative to the rotation cover 20.

The shaft 32 may be a columnar structure, extending in the imaginary central axis AX1. In other words, the imaginary central axis AX1 extends through the center of the shaft 32. The shaft 32 is rotated about the imaginary central axis AX1 relative to the fastening body 11. The partition element 12 includes a shaft hole 121, and the imaginary central axis AX1 extends through the center of the shaft hole 121. The shaft 32 is rotatably disposed in the shaft hole 121. The driving structure 33 surrounds the shaft 32, and is used to rotate the screw bolt 10. In the embodiment, the driving structure 33 includes a teeth portion 331. When the teeth portion 331 is engaged with the engaging protrusion 14, the connection element 30 and the fastening body 11 are rotatable with the rotation cover 20 by rotating the rotation cover 20.

The holding structure 34 is disposed on the end of the shaft 32, and extends through the temporary element 13. The holding structure 34 can be used to prevent the temporary element 13 from being separated from the connection element 30. In the embodiment, the holding structure 34 may be a screw. The holding structure 34 includes a rod portion 341 and a blocking protrusion 342. One end of the rod portion 341 is affixed to the end of the shaft 32, and the other end of the rod portion 341 is affixed to the blocking protrusion 342. The rod portion 341 of the holding structure 34 extends through the temporary element 13. The temporary element 13 is restricted between blocking protrusion 342 and the end of the shaft 32. Moreover, the length of the rod portion 341 in the longitudinal direction D1 is longer than the length of the temporary element 13 in the longitudinal direction D1. Therefore, when the temporary element 13 is broken off or detached from the partition element 12, the temporary element 13 can be moved on the rod portion 341 in the longitudinal direction D1.

In the embodiment, the shaft 32 further includes a fitting groove 321, formed on the end of the shaft 32. The temporary element 13 further includes a fitting protrusion 131. When the temporary element 13 is affixed to the partition element 12, the fitting protrusion 131 is in the fitting groove 321. Moreover, the fitting protrusion 131 may be a polygon, and the fitting groove 321 may be a polygon matching the fitting protrusion 131. When the temporary element 13 is affixed to the partition element 12, the shaft 32, the fitting protrusion 131, and the partition element 12 are rotatable with the rotation cover 20 by rotating the rotation cover 20.

The inner elastic element 40 is disposed in the fitting groove 321 of the shaft 32, and abuts the fitting protrusion 131. The inner elastic element 40 may be a spring, or an elastic material, such as rubber. When the temporary element 13 is broken off from or detached the partition element 12, the inner elastic element 40 pushes the temporary element 13 out of from the fitting groove 321. In another embodiment, the anti-tamper securing mechanism 1 may not include the inner elastic element 40.

The main elastic element 50 is disposed between the connection element 30 and the partition element 12. Moreover, the main elastic element 50 is between the shaft 32 and the driving structure 33. In the embodiment, the main elastic element 50 may be a spring. The main elastic element 50 elastically resists against the connection element 30 so as to maintain the connection element 30 at an initial position shown in FIG. 1.

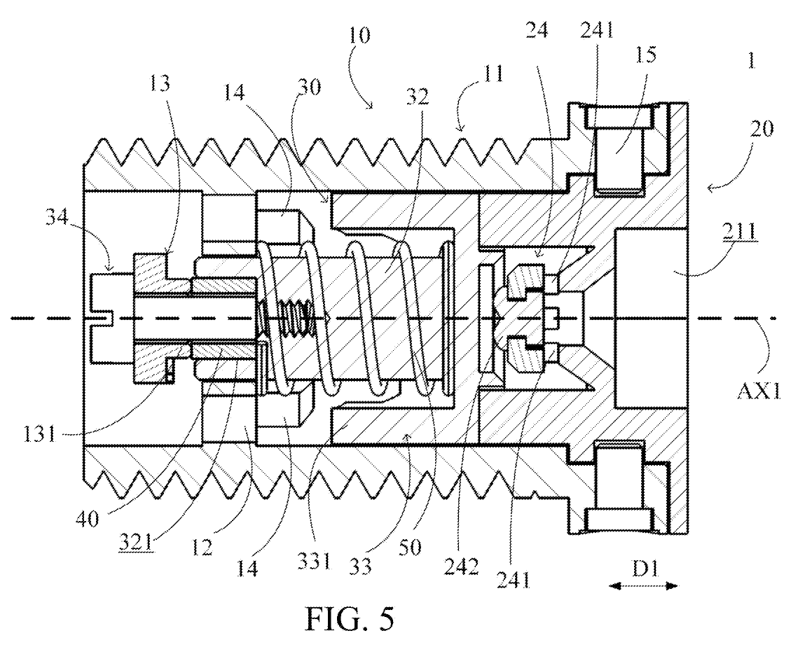

FIG. 5 and FIG. 6 are cross-sectional views of the anti-tamper securing mechanism 1 in operation processes in accordance with an embodiment of the present disclosure. In step 1, as shown in FIG. 1 to FIG. 4, the fastening body 11 of the screw bolt 10 is fastened in the objects W1 by rotating the rotation cover 20 using the securing tool. At this time, the temporary element 13 is attached to the partition element 12, and the connection element 30 is at the initial position. The teeth portion 331 of the driving structure 33 of the connection element 30 is separated from the engaging protrusion 14 of the screw bolt 10. The fitting protrusion 131 of the temporary element 13 is in the fitting groove 321 of the connection element 30. Therefore, the connection element 30, the temporary element 13, and the fastening body 11 are rotatable with the rotation cover 20 by rotating the rotation cover 20, thereby securing the objects W1.

In step 2, when fastening body 11 is fastened to the object W1, the rotation cover 20 is further rotated to make the connection element 30 rotate relative to the fastening body 11 until the temporary element 12 is broken off or detached from the partition element 12 as shown in FIG. 5. At this the time, the inner elastic element 40 pushes the temporary element 13 out of from the fitting groove 321. As shown in FIG. 5, when the user continues to use the securing tool to rotate the rotation cover 20 in the clockwise direction or in the counterclockwise direction, the fastening body 11 cannot be rotated again. Therefore, the anti-tamper function of the anti-tamper securing mechanism 1 can be achieved.

When the user wants to remove the anti-tamper securing mechanism 1 from the objects W1, the user can perform the following steps 3 and 4. In the step 3, as shown in FIG. 6, the disassembly tool T1 is inserted into the tool groove 211 to connect to the rotation cover 20. Afterward, the connection element 30 is moved toward the partition element 13 by the disassembly tool T1 so that the teeth portion 331 of the connection element 30 is engaged with the engaging protrusion 14. In the embodiment, the disassembly tool T1 is connected to an air pump. The air pump pumps pressurized air in to the fastening body 11 through the end of the disassembly tool T1. Therefore, the disassembly tool T1 can pump air into the fastening body 11 through the ventilation opening 24, and the connection element 30 is pushed to move from the initial position of FIG. 5 in the longitudinal direction D1 to the engaged position in FIG. 6, so that the teeth portion 331 of the driving structure 33 of the connection element 30 is engaged with the engaging protrusion 14 of the screw bolt 10.

In the embodiment, the end of the ventilation post 24 has an obstruction wall 242. Therefore, it is hard to push the connection element 30 through the rotation cover 20 in the longitudinal direction D1 by a needle-shaped rod, thereby increasing the difficulty of disassembling the anti-tamper securing mechanism 1. In another embodiment, the ventilation post 24 may not include the obstruction wall 242, and the ventilation opening 241 of the ventilation post 24 is on the imaginary central axis AX1. Therefore, the user can disassemble the anti-tamper securing mechanism 1 by using the disassembly tool T1 which has a needle-shaped rod at the end.

In the step 4, the rotation cover 20 is rotated by the disassembly tool T1 so that the connection element 30 drives the fastening body 11 to rotate relative to the object W1, thereby disassembling the screw bolt 10 from the object W1. In other words, when the rotation cover 20 is rotated, the connection element 30 and the fastening body 11 is rotates with the rotation cover 20.

In conclusion, the anti-tamper securing mechanism 1 of the present invention can be fastened to the objects W1 by a conventional screwdriver, and the anti-tamper securing mechanism 1 cannot be disassembled by the conventional screwdriver. Therefore, the anti-tamper function of the anti-tamper securing mechanism 1 can be achieved.

Many details are often found in the relevant art, thus many such details are neither shown nor described. Even though numerous characteristics and advantages of the present technology have been set forth in the foregoing description, together with details of the structure and function of the present disclosure, the disclosure is illustrative only, and changes may be made in the detail, especially in matters of shape, size, and arrangement of the parts within the principles of the present disclosure, up to and including the full extent established by the broad general meaning of the terms used in the claims. It will, therefore, be appreciated that the embodiments described above may be modified within the scope of the claims.

What is claimed is:

1. An anti-tamper securing mechanism comprising:
a screw bolt comprising:
a fastening body;
a partition element affixed within the fastening body; and
a temporary element attachable to the partition element;
a rotation cover rotatably disposed in the fastening body;
a connection element movably and rotatably disposed in the fastening body, and connected to the rotation cover; and
a main elastic element disposed between the connection element and the partition element,
wherein when the temporary element is attached to the partition element, the connection element contacts the temporary element, and the connection element, the temporary element, and the fastening body are rotatable with the rotation cover; and
when the fastening body is fastened on an object, the temporary element is detached from the partition element by further rotating the rotation cover relative to the fastening body.

2. The anti-tamper securing mechanism as claimed in claim 1, wherein the screw bolt further comprises a engaging protrusion affixed within the fastening body, wherein the fastening body is detachable from the object,
when the connection element is engaged with the engaging protrusion by connecting a disassembly tool to the rotation cover, and rotating the rotation cover by the disassembly tool thereby rotating the fastening body with the rotation cover.

3. The anti-tamper securing mechanism as claimed in claim 2, wherein the rotation cover comprises a ventilation opening, when the disassembly tool pumps air into the fastening body through the ventilation opening, the connection element is pushed to engage with the engaging protrusion.

4. The anti-tamper securing mechanism as claimed in claim 2, wherein the connection element is separated from the engaging protrusion when the temporary element is attached to the partition element.

5. The anti-tamper securing mechanism as claimed in claim 1, wherein the rotation cover comprises a position groove, the screw bolt further comprises a limiting element in the position groove, the position groove is an annular structure configured to restrict the rotation cover to rotate relative to the fastening body about an imaginary central axis.

6. The anti-tamper securing mechanism as claimed in claim 1, wherein the connection element comprises a restriction slot, the rotation cover comprises a restriction rib in the restriction slot, and the connection element is restricted to be moved in a longitudinal direction relative to the fastening body and the rotation cover by the restriction slot and the restriction rib.

7. The anti-tamper securing mechanism as claimed in claim 1, wherein the partition element comprises a shaft hole, and the connection element comprises:
a shaft in the shaft hole; and
a driving structure surrounding the shaft, and configured to rotate the screw bolt,
wherein the main elastic element is between the shaft and the driving structure.

8. The anti-tamper securing mechanism as claimed in claim 7, wherein the connection element further comprises a holding structure disposed on the shaft, wherein the holding structure is extended through the temporary element.

9. The anti-tamper securing mechanism as claimed in claim 7, wherein the shaft comprises a fitting groove, the temporary element further comprises a fitting protrusion, and the fitting protrusion is in the fitting groove when the temporary element is attached to the partition element.

10. The anti-tamper securing mechanism as claimed in claim 9, further comprising an inner elastic element disposed in the fitting groove, wherein the inner elastic element pushes the temporary element when the temporary element is detached from the partition element.

11. An operation method applied in an anti-tamper securing mechanism, the operation method comprising:
block (a): rotating a rotation cover of the anti-tamper securing mechanism to fasten a fastening body of a screw bolt of the anti-tamper securing mechanism on objects, wherein the screw bolt further comprises a partition element disposed in the fastening body, and affixed to a temporary element of the partition element, and the anti-tamper securing mechanism further comprises a connection element moveably and rotatably disposed in the fastening body, and connected to the rotation cover; and
block (b): further rotating the rotation cover to rotate the connection element relative to the fastening body until the temporary element is broken off from the partition element.

12. The operation method as claimed in claim 11, wherein the block (a) further comprises:
rotating the connection element, the temporary element, and the fastening body with the rotation cover relative to the objects.

13. The operation method as claimed in claim 11, further comprising:
block (c): mounting a disassembly tool to the rotation cover to engage the connection element to an engaging protrusion of the screw bolt.

14. The operation method as claimed in claim 13, wherein the block (c) further comprises:
pumping air into the fastening body through a ventilation opening of the rotation cover by the disassembly tool, until the connection element is pushed to engage with the engaging protrusion.

15. The operation method as claimed in claim 13, further comprising:
block (d): rotating the rotation cover by the disassembly tool, so that the connection element drives the fastening body to rotate relative to the objects, thereby removing the screw bolt from the objects.
